(19) United States
(12) Patent Application Publication
(10) Pub. No.: US 2010/0112733 A1
(43) Pub. Date: May 6, 2010

(54) MEASURING DEVICE, EXPOSURE APPARATUS, AND DEVICE MANUFACTURING METHOD

(75) Inventor: Yasunori Furukawa, Utsunomiya-shi (JP)

Correspondence Address: CANON U.S.A. INC. INTELLECTUAL PROPERTY DIVISION, 15975 ALTON PARKWAY, IRVINE, CA, 92618-3731, US

(73) Assignee: CANON KABUSHIKI KAISHA, Tokyo (JP)

(21) Appl. No.: 12/580,875

(22) Filed: Oct. 16, 2009

(30) Foreign Application Priority Data
Oct. 30, 2008 (JP) 2008-279873

(51) Int. Cl. H01L 21/66; G01B 9/02; H01L 21/26

(52) U.S. Cl. 438/16; 356/521; 438/795; 257/E21.529; 257/E21.328

(57) ABSTRACT

A measuring device configured to measure a wave aberration of an optical system to be measured includes a reflection optical element for reflecting light, having passed through a mask and the optical system to be measured, into the optical system to be measured, and a detector for detecting an interference fringe of light having passed through pinholes and openings. The mask has at least three pinhole-opening pairs, each including one pinhole and one opening having a larger diameter than the pinhole that are arranged point-symmetrically, the three pinhole-opening pairs having the common center of symmetry. The light to be measured formed in two of the three pairs is made to interfere with the reference light formed in the remaining pair, or, the light to be measured formed in one of the three pairs is made to interfere with the reference light formed in the other two pairs.

### BACKGROUND OF THE INVENTION

1. Field of the Invention

The present invention relates to measuring devices, exposure apparatuses, and device manufacturing methods.

2. Description of the Related Art

In the field of photolithography, projection exposure apparatuses have been used to manufacture integrated circuits such as large scale integrated circuits (LSIs), image pickup devices such as CCD sensors, display devices such as liquid crystal panels, and semiconductor devices such as magnetic heads. Such a projection exposure apparatus transfers a pattern formed on a reticle (mask) onto a substrate, such as a wafer, through a projection optical system. Because the projection exposure apparatus needs to accurately transfer the pattern on the reticle to the wafer, it is important to use the projection optical system with high imaging performance and reduced aberration.

In recent years, because patterns of semiconductor devices are becoming finer relative to the wavelengths of light sources, the resolution of the patterns is becoming more sensitive to the aberration of the projection optical systems. Therefore, it is necessary to accurately measure the optical property (for example, wave aberration) of the projection optical system in a state in which the projection optical system is installed in the apparatus so that the apparatus can actually perform exposure.

A space-saving small measuring device is particularly desirable as the measuring device for measuring the wave aberration of the projection optical system in the exposure apparatus. Thus, single-path interferometers, such as point diffraction interferometers (PDIs) and shearing interferometers, (see Japanese Patent Laid-Open Nos. 2005-159213, 2000-97666, and 2003-161672) and double-path interferometers (see Japanese Patent Laid-Open No. 2003-14415) have been proposed.

In the single-path interferometers disclosed in Japanese Patent Laid-Open Nos. 2005-159213, 2000-97666, and 2003-161672, a measuring device for measuring the interference fringe is disposed on the image side of an optical system to be measured. In the cases where the optical system to be measured has a high numerical aperture (NA) and where the space under the optical system is filled with liquid, the placement of the measuring device on the image side involves many physical restrictions. Furthermore, in such cases, the measurement accuracy decreases because the distortion of the interference fringe, as well as a decrease in light intensity at the periphery of the pupil, becomes noticeable.

On the other hand, the double-path interferometer disclosed in Japanese Patent Laid-Open No. 2003-14415 has a simple structure because it is only necessary that a reflection optical element is disposed on the image side of the optical system to be measured. However, because the mask has only a pair of large and small pinholes that limit the light intensity, the light intensity on the image pickup surface of the measuring device is insufficient, decreasing the measurement accuracy. In addition, the interferometer is susceptible to the disturbance.

### SUMMARY OF THE INVENTION

In view of the above-described circumstances, the present invention provides a measuring device capable of accurately measuring the wave aberration of an optical system to be measured using a simple structure, an exposure apparatus and a device manufacturing method using the exposure apparatus, and a measuring device for measuring the shape of a surface to be measured.

The present invention provides a measuring device configured to measure a wave aberration of an optical system to be measured. The measuring device includes an illumination optical system configured to illuminate a mask disposed on a plane to be illuminated with light from a light source, a reflection optical element configured to reflect light, having passed through the mask and the optical system to be measured, into the optical system to be measured, and a detector configured to detect an interference fringe formed by the light having passed through the mask. The mask has at least three pinhole-opening pairs, each including one pinhole and one opening having a larger diameter than the pinhole that are arranged point-symmetrically, the three pinhole-opening pairs having a common center of symmetry. In each of the pinhole-opening pairs, light having passed through the pinhole and the optical system to be measured, been reflected at the reflection optical element, and passed through the optical system to be measured and the opening serves as light to be measured, and light having passed through the opening and the optical system to be measured, been reflected at the reflection optical element, and passed through the optical system to be measured and the pinhole serves as reference light. The light to be measured formed in at least two of the three pairs is made to interfere with the reference light formed in the remaining pair, or, the light to be measured formed in at least one of the three pairs is made to interfere with the reference light formed in the other two pairs.

The present invention also provides a measuring device configured to measure the shape of a surface to be measured. The measuring device includes an illumination optical system configured to illuminate a mask disposed on a plane to be illuminated with light from a light source, and a detector configured to detect an interference fringe formed by the light having passed through the mask. The mask has at least three pinhole-opening pairs, each including one pinhole and one opening having a larger diameter than the pinhole that are arranged point-symmetrically, the three pinhole-opening pairs having a common center of symmetry. In each of the pinhole-opening pairs, light having passed through the pinhole, been reflected at the surface to be measured, and passed through the opening serves as light to be measured, and light having passed through the opening, been reflected at the surface to be measured, and passed through the pinhole serves as reference light. The light to be measured formed in at least two of the three pairs is made to interfere with the reference light formed in the remaining pair, or, the light to be measured formed in at least one of the three pairs is made to interfere with the reference light formed in the other two pairs.

Further features of the present invention will become apparent from the following description of exemplary embodiments with reference to the attached drawings.

### BRIEF DESCRIPTION OF THE DRAWINGS

The accompanying drawings, which are incorporated in and constitute a part of the specification, illustrate embodiments of the invention and, together with the description, serve to explain the principles of the invention.

FIG. 1 is a schematic view of a measuring device according to a first embodiment of the present invention.

FIG. 2 is a plan view of a mask.

FIG. 3 is a diagram for explaining the structure of the mask.

FIGS. 4A to 4E are diagrams showing the effective light source distributions.

FIG. 5 is a diagram showing the coherence on the mask.

FIG. 6 is a diagram showing the image of the interference fringe captured when the mask is used.

FIGS. 7A to 7C are diagrams showing the effective light source distributions.

FIGS. 8A to 8C are diagrams showing the effective light source distributions.

FIGS. 9A to 9C are diagrams showing the effective light source distributions.

FIGS. 10A to 10C are diagrams showing the effective light source distributions.

FIG. 11 is a diagram showing a diffraction grating serving as a light splitter.

FIGS. 12A to 12C are diagrams showing diffraction gratings serving as light splitters.

FIG. 13 is a plan view of a mask.

FIG. 14 is a diagram for explaining the structure of the mask.

FIGS. 15A to 15E are diagrams showing the effective light source distributions.

FIG. 16 is a diagram showing the image of the interference fringe captured when the mask is used.

FIGS. 17A and 17B are diagrams showing the effective light source distributions.

FIGS. 18A and 18B are diagrams showing the effective light source distributions.

FIGS. 19A and 19B are diagrams showing the effective light source distributions.

FIGS. 20A and 20B are diagrams showing the effective light source distributions.

FIG. 21 is a diagram showing a diffraction grating serving as a light splitter.

FIGS. 22A and 22B are diagrams showing diffraction gratings serving as light splitters.

FIG. 23 is a schematic view of a measuring device according to a third embodiment of the present invention.

### DESCRIPTION OF THE EMBODIMENTS

Embodiments of the present invention will be described below with reference to the attached drawings. Note that like reference numerals refer to like parts throughout the various views, and repetitive explanations will be omitted.

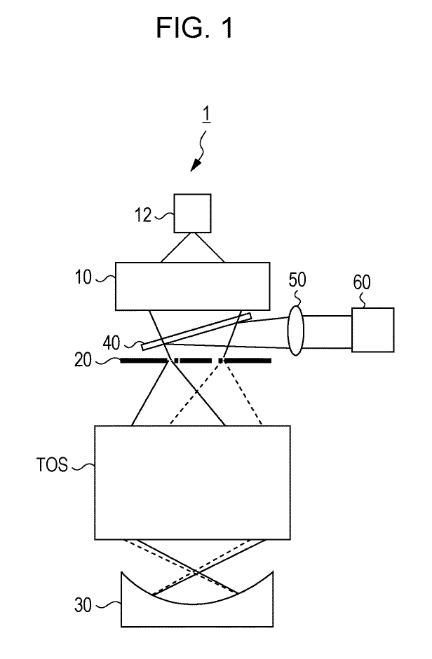

A first embodiment of the present invention will be described below. FIG. 1 is a schematic view of a measuring device for measuring the optical property of an optical system TOS to be measured. In this embodiment, in a state in which a measuring device is incorporated in an exposure apparatus, the wave aberration of a projection optical system of an exposure apparatus, serving as the optical system TOS, is measured. As shown in FIG. 1, a measuring device 1 includes an illumination optical system 10, a mirror 30, a half mirror 40, an image-forming lens 50, and a detector 60. A mask 20 is disposed on a plane to be illuminated of the illumination optical system 10, which is positioned between the half mirror 40 and the optical system TOS.

A light source 12 employs a light source similar to that of the exposure apparatus, such as an argon fluoride (ArF) excimer laser having a wavelength of about 193 nm or a krypton fluoride (KrF) excimer laser having a wavelength of about 248 nm.

The illumination optical system 10 is an optical system that illuminates the mask 20 with Koehler illumination. An illumination optical system of the exposure apparatus for transferring a device pattern to a wafer may be used as the illumination optical system 10. The illumination optical system 10 includes an optical system that forms a light intensity distribution (effective light sources) on a pupil plane of the illumination optical system (for example, a prism, a diffractive optical element, a computer generated hologram (CGH), and an aperture stop), an optical integrator (such as a fly's eye lens), and a condenser optical system.

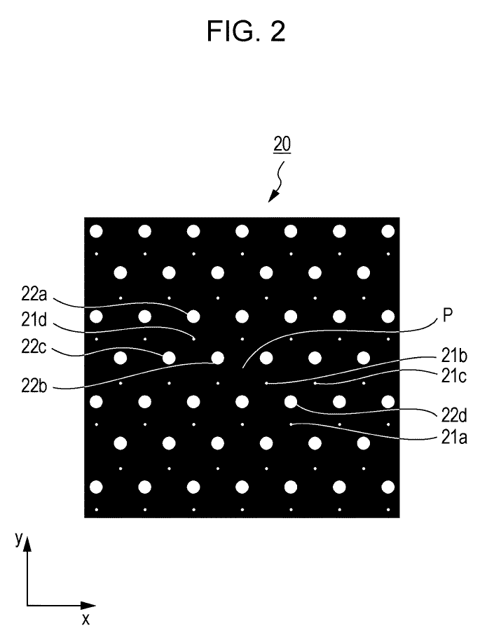

The mask 20 is an object-side mask disposed at an object plane of the optical system TOS. FIG. 2 is a plan view of the mask 20. As shown in FIG. 2, the mask 20 has a plurality of pinholes and openings that are arranged periodically on a two-dimensional surface. As will be described below, the pinholes and openings in the mask 20 are arranged at such a distance from each other that the light beam from at least one pinhole and the light beam from at least one opening have coherence. Hereinafter, the pinholes arranged in the mask 20 will be collectively referred to as the pinholes 21, and the openings arranged in the mask 20, having a larger diameter than the pinholes 21, will be collectively referred to as the openings 22.

Where NAob is the numerical aperture on the object side (hereinafter, “object side NA”) of the optical system TOS, and λ is the wavelength of the light source 12, the diameter D of the pinholes 21 satisfies Expression 1 below.

D≦1.22×λ/NAob Expression 1

Because the pinholes 21 have a diameter D that is equal to or less than the diffraction limit based on the object side NA of the optical system TOS, the wave of light having passed through the pinholes 21 (reference light) is an ideal spherical wave. The openings 22 have a diameter such that the aberration of the optical system TOS is not eliminated when light having passed through the projection optical system passes through the openings 22. In this embodiment, the pinholes 21 have a diameter of about 0.1 μm, and the openings 22 have a diameter of several μm. However, it is not necessary that all the pinholes or openings have the same diameter.

Light (indicated by a thick solid line in FIG. 1) having passed through one opening in the mask 20 passes through the optical system TOS and is incident on the mirror 30 serving as the reflection optical element. The mirror 30 reflects the light, and the reflected light (indicated by a dotted line in FIG. 1) is incident on the optical system TOS, and then, on the mask 20.

The mirror 30 and the mask 20 are arranged such that light having passed through one opening in the mask 20 and been reflected at the mirror 30 is condensed at one pinhole, and such that light having passed through one pinhole in the mask 20 and been reflected at the mirror 30 is condensed at one opening. The mirror 30 may be a spherical mirror.

The half mirror 40 and the image-forming lens 50 serve to guide light having passed through the optical system TOS, been reflected at the mirror 30, and passed through the mask 20 to the detector 60.

The detector 60 is an image pickup device formed of a photoelectric conversion element, such as a CCD camera. The detector 60 detects an interference pattern formed by the light beams from the pinholes and openings in the mask 20. The data on the interference fringe, detected by the detector 60, is sent to an arithmetic processing unit (calculation unit), where the wave aberration of the optical system TOS etc. are calculated.

The relationship between the illumination optical system 10, the mask 20, and the mirror 30 will be described in detail below.

First, the illumination optical system 10 will be described. In the exposure apparatus, when the light beam illuminating the reticle has a high spatial coherence, the light beams having passed through the pattern formed on the reticle interfere with each other, making it impossible to transfer the pattern to the wafer (substrate). Thus, the spatial coherence of the light beam illuminating the reticle is reduced by a fly's eye lens or the like. In other words, the illumination optical system 10 illuminates the mask 20 with a light beam having a reduced spatial coherence, i.e., a low coherence for the interferometer. Therefore, the pinholes and openings in the mask and the effective light source distribution are selected to obtain a high-contrast interference fringe with the illumination optical system for exposing substrates.

Now, λ represents the wavelength of the light source 12, f represents the focal length of the illumination optical system 10, (ε, η) represents the coordinate normalized by fλ, and u (ε, η) represents the effective light source distribution. Where the coordinate of the mask 20 is (x, y), the distribution of coherence with respect to the origin of the mask 20 (0, 0) (i.e., mutual intensity Γ) is given by Expression 2 below. Expression 2 is called van Cittert-Zernike theorem, and the mutual intensity is obtained by Fourier-transforming the effective light source distribution. Note that (ε, η) and (x, y) are orthogonal coordinates.

Γ(x,y)=∫u(ε,η)exp{i2π(εx+ηy)}dεdη Expression 2

Now, (εj, ηj) (j is a natural number) represents the position of the light-emitting portion in the effective light source distribution, (xi, yi) (i is a natural number) represents the positions of the plurality of pinholes 21 in the mask 20, and (Xk, Yk) (k is a natural number) represents the positions of the plurality of openings 22 in the mask 20. When Expression 3, below, is satisfied, the light beams from the pinholes positioned at (xi, yi) and the light beams from the openings positioned at (Xk, Yk) have coherence, increasing the contrast of the interference fringe formed by these light beams. Note that n is an integer.

εj*xi+ηj*yi−(εj*Xk+ηj*Yk)=n Expression 3

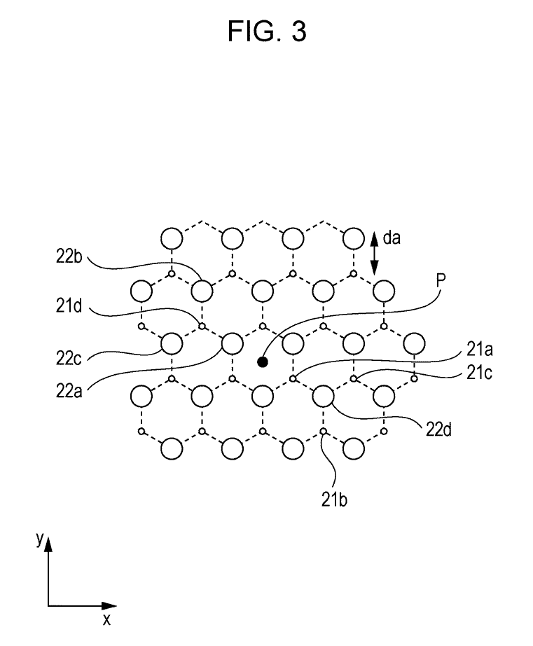

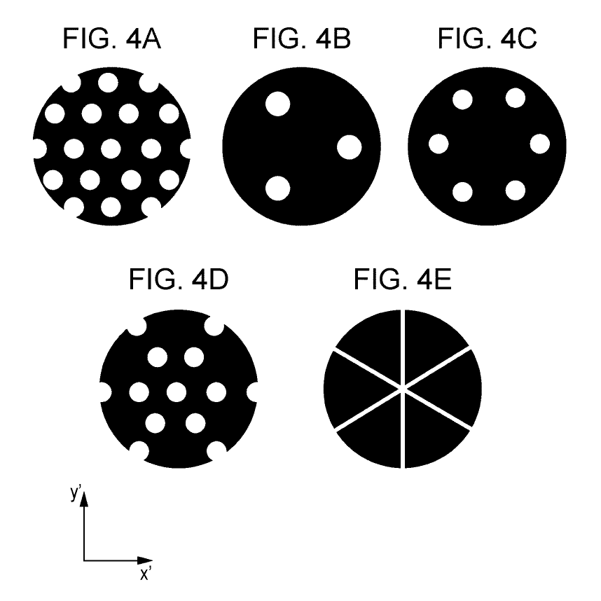

This embodiment uses the mask 20 shown in FIGS. 2 and 3 and the effective light source distributions shown in FIGS. 4A to 4E, according to Expression 3.

As shown in FIG. 3, the pinholes 21 and openings 22 in the mask 20 are alternately arranged at the vertices of honeycombed virtual regular hexagons. One pinhole and one opening, having a larger diameter than the pinhole, forming a pair, are arranged point-symmetrically with respect to a point P. More specifically, a pinhole 21a and an opening 22a, forming a pair, are arranged point-symmetrically with respect to the point P. Similarly, a pinhole 21b and an opening 22b, a pinhole 21c and an opening 22c, and a pinhole 21d and an opening 22d are arranged point-symmetrically with respect to the point P.

Assuming that light passes through the mask 20 at the point P, the mirror 30 is disposed such that the focal position (center of curvature) thereof is aligned with the position where the optical system TOS condenses light having passed at the point P. The coordinate origin of the optical system TOS on the object side is disposed at the point P and that on the image side is disposed at the position where the optical system TOS condenses light having passed at the point P.

When the mask 20 has an opening at (4X, 4Y), light having passed therethrough and is condensed by the optical system TOS (one-fourth reduction system) at (−X, −Y) on the image plane. The light having passed through the optical system TOS is reflected at the mirror 30 and is condensed at (X, Y) on the image plane. The light then passes again through the optical system TOS and is condensed at (−4X, −4Y) on the object plane. For example, light having passed through the opening 22a passes the optical system TOS, is reflected at the mirror 30, passes again through the optical system TOS, and is condensed at the position point-symmetrical to the opening 22a with respect to the point P (pinhole 21a). Similarly, light having passed through the opening 22b (22c) passes through the optical system TOS, is reflected at the mirror 30, passes again through the optical system TOS, and passes through the pinhole 21b (21c). These rays of light are reference waves and become ideal spherical waves by passing through the pinholes 21. On the other hand, light having passed through the pinhole 21d passes through the optical system TOS, is reflected at the mirror 30, passes again through the optical system TOS, and passes through the opening 22d. This is light to be measured. Because the light has passed through the pinhole 21d before passing through the optical system TOS, the light is not affected by the aberration of the illumination optical system, and, because the light has passed through the opening 22d after passing through the optical system TOS, the wave contains the aberration of the optical system TOS.

The illumination optical system 10, in order to illuminate the mask 20 to form a high contrast interference fringe, adjusts the effective light source distribution and controls the coherence length and coherence direction of the light beams having passed through the mask 20 so that only intended light beams interfere with each other. In other words, the illumination optical system 10 forms the effective light source distribution such that the light beams from the pinholes 21 in the mask 20 are coherent only with those from the openings 22 adjacent to the pinholes 21. For example, the illumination optical system 10 forms the effective light source distributions as shown in FIGS. 4A to 4E. These effective light source distributions are formed such that the light beam from the opening 22d is coherent only with those from, among the pinholes 21, the pinholes 21a to 21c disposed at positions shifted by the same distance from the opening 22d in three directions.

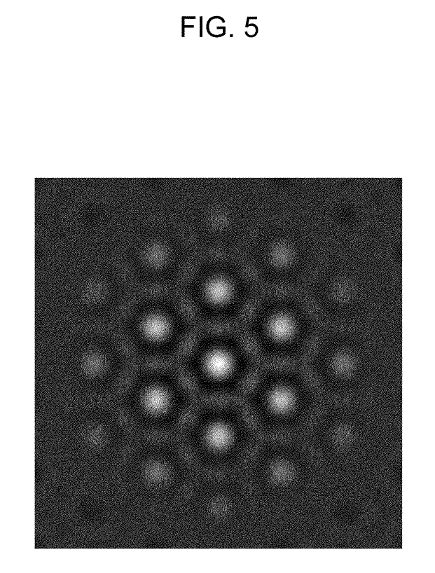

More specifically, when the effective light source distribution shown in FIG. 4A is used, the mutual intensity has peaks at six-fold symmetry positions, as shown in FIG. 5. Because the opening 22d is provided at the origin position and the pinholes 21a to 21c are provided at the peak positions, the light beam from the opening 22d interferes with the light beams from the pinholes 21a to 21c. From the mutual intensity in FIG. 5, the light beams from the pinholes other than the pinholes 21a to 21c hardly interfere with the light beam from the opening 22d. Not only the pinholes 21a to 21c but also other pinholes and openings in the mask 20 have such a relationship that only the light beams from adjacent openings and pinholes interfere with each other. That is, among four opening-pinhole pairs, light to be measured, formed at each of three pairs, is made to interfere with the reference light formed at the remaining pair. Alternatively, among four opening-pinhole pairs, light to be measured, formed at one pair, is made to interfere with the reference light formed at each of the other three pairs.

FIGS. 4A to 4E are schematic views showing examples of effective light source distributions formed by the illumination optical system 10. White portions in black circles are light-emitting portions. The effective light source distributions also correspond to the light angle distributions on the mask 20, and x′ and y′ directions correspond respectively to x and y directions in FIGS. 2 and 3. A case where a region including, for example, the pinhole 21d and the openings 22a to 22c is illuminated with these effective light source distributions will be discussed. After light from the mask 20 passes through the optical system TOS, is reflected at the mirror 30, and passes again through the optical system TOS, rays having passed through the pinholes 21a, 21b, and 21c each interfere with the ray having passed through the openings 22d.

Furthermore, in the case where the entire surface of the mask 20 is illuminated with the effective light source distributions shown in FIGS. 4A to 4E, the centers of the interference fringes of the rays having passed through, for example, the pinholes 21a, 21b, and 21c and the ray having passed through the opening 22d are superimposed on one another so as to be shifted in six directions by an integral multiple of Formula 1.

√3da Formula 1

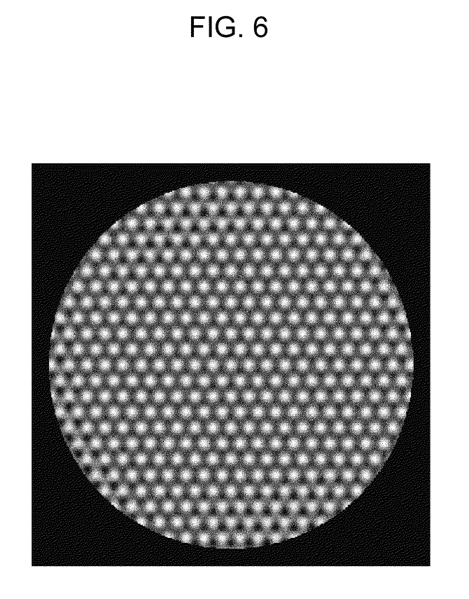

Denoted by da is the distance between the adjacent pinhole and opening. As a result, the interference fringe as shown in FIG. 6 is formed on the detector 60.

Because the distance da is sufficiently small and the pinholes are arranged at a high density, the measurement light intensity can be increased to improve the measurement accuracy. Note that, by increasing the region where the pinholes and the openings are disposed (i.e., the region to be illuminated), the light intensity can be further increased. However, because the interference fringes of the rays having passed through the pinholes 21a, 21b, and 21c and the ray having passed through the opening 22d are superimposed on one another such that the peaks thereof are shifted, an increase in the aforementioned region may decrease the contrast. Accordingly, it is desirable that the region where the pinholes and openings are disposed (i.e., the region to be illuminated) in the mask 20 be equal to or smaller than one tenth of the pitch of the interference fringes.

The arithmetic processing unit (calculation unit) calculates the phase information of the wave aberration of the optical system TOS from the interference fringe whose image is captured by the detector 60. For the calculation of the phase information, an electron moiré method or a Fourier transformation method are used. These methods enables the phase information of the wave aberration of the optical system TOS to be obtained from one interference fringe, making it possible to measure the wave aberration of the optical system TOS in a short time. When the electron moiré method is used, cosine functions having the same frequency as the interference fringe and a plurality of phases (for example, 0°, 90°, 180°, and 270° are used. By multiplying the interference fringe by each function and by performing the Fourier transformation and an arctangent calculation, the wave aberration can be obtained. At this time, three types of cosine functions, whose frequencies are different from one another by 120°, are used. When the Fourier transformation method is used, because peaks with six-fold symmetry appear in the Fourier space upon Fourier transformation of the interference fringe, information near the three peaks that exist every 120° may be used. Three wave aberrations can be obtained by the electron moiré method or the Fourier transformation method, and, if there is no measurement error at all, the three wave aberrations are equal. However, if there is a measurement error, the three wave aberrations are often different from one another. Thus, it is desirable to reduce the measurement error by, for example, calculating the average of the three wave aberrations.

Although there are system errors of the measuring device, such as manufacturing errors of the mirror 30 and the aberration of the image-forming lens 50, the wave aberration of the optical system TOS may be obtained by measuring these errors in advance and subtracting them from the measured wave aberration.

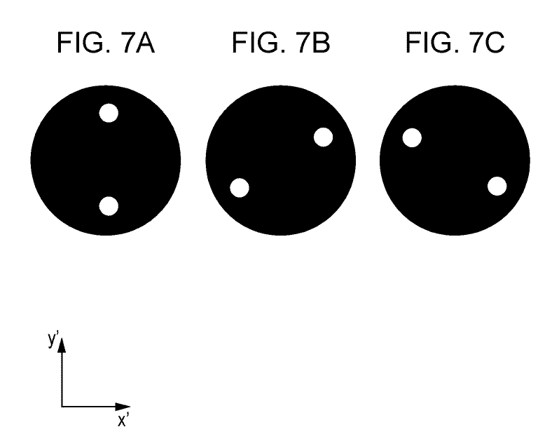

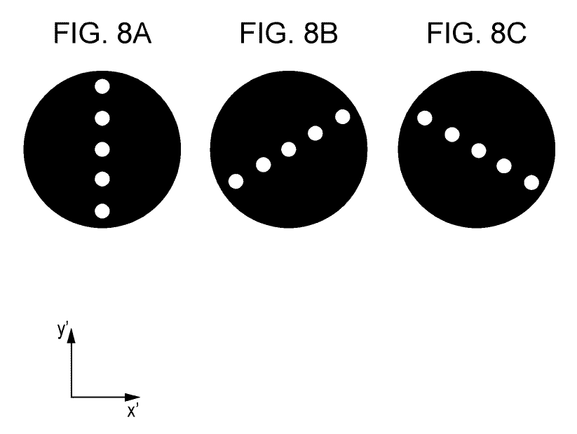

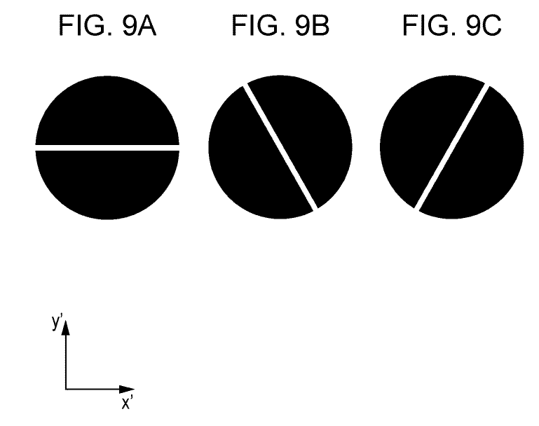

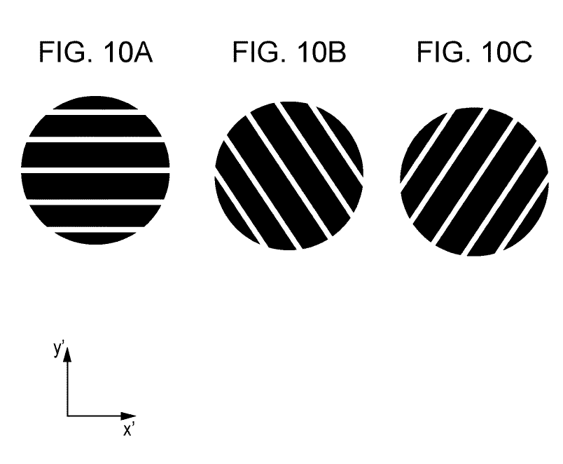

The measurement can also be performed by illuminating the mask 20 with the illumination optical system 10 forming the effective light source distributions as shown in FIGS. 7A to 7C. More specifically, by forming a double-path interferometer by illuminating the mask 20 with the effective light source distribution shown in any one of FIGS. 7A to 7C and by making the light beams having passed through the adjacent pinhole and opening interfere with each other, a high-contrast interference fringe can be formed. Then, by capturing the image of the interference fringe with the detector 60, the wave aberration of the optical system TOS can be obtained. The same is true with the effective light sources shown in FIGS. 8A to 8C, FIGS. 9A to 9C, and FIGS. 10A to 10C.

More specifically, using the effective light source distributions shown in FIGS. 7A, 8A, 9A, and 10A, the coherence between the light beam having passed through the pinhole 22d and that having passed through the opening 21b is increased to detect the interference pattern. Similarly, using the effective light source distributions shown in FIGS. 7B, 8B, 9B, and 10B, the coherence between the light beam having passed through the pinhole 22d and that having passed through the opening 21c is increased to detect the interference pattern. In addition, using the effective light source distributions shown in FIGS. 7C, 8C, 9C, and 10C, the coherence between the light beam having passed through the pinhole 22d and that having passed through the opening 21a is increased to detect the interference pattern.

In each of the cases where the effective light sources shown in FIGS. 7A, 8A, 9A, and 10A are used, where the effective light sources shown in FIGS. 7B, 8B, 9B, and 10B are used, and where the effective light sources shown in FIGS. 7C, 8C, 9C, and 10C are used, the interference fringe appears only in one direction. Therefore, in an analysis using, for example, the Fourier transformation method, the Fourier spectrum of each of the three interference patterns has two peaks that are separated from each other, which reduces sources of error and improves the measurement accuracy.

Although the illumination optical system 10 forms three effective light source distributions, namely, A to C in FIGS. 7 to 10, it is also possible that the illumination optical system 10 forms one effective light source distribution, for example, A in FIGS. 7 to 10, and the optical system TOS is rotated. Alternatively, one of the three effective light source distributions, namely, A to C in FIGS. 7 to 10, may be rotated.

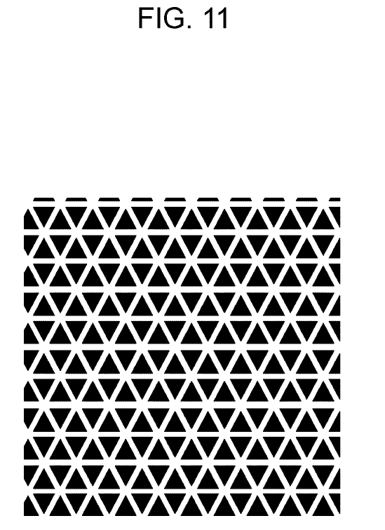

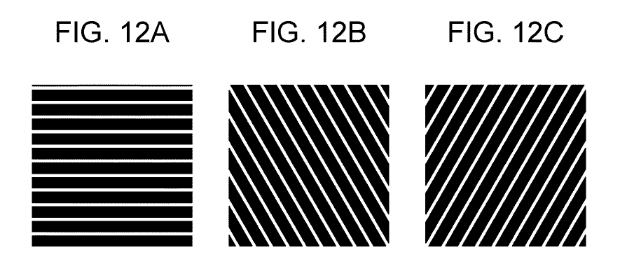

Moreover, to control the coherence, instead of the effective light source distributions shown in FIGS. 4A to 4E, a light splitter, such as a diffraction grating shown in FIG. 11, a CGH, or the like may be used. Furthermore, instead of the effective light source distributions shown in FIGS. 7A to 7C, 8A to 8C, 9A to 9c, and 10A to 10C, three diffraction gratings shown in FIGS. 12A to 12C may be used. White lines in FIGS. 11 and 12A to 12C indicate transmitting portions. Where Pg represents the pitch of the transmitting portions of the diffraction grating (diffraction grating pitch) and Lg represents the distance between the diffraction grating and the mask 20, the diffraction grating pitch Pg and the distance Lg satisfy the Expression 4 below.

Pg=(m*λ*Lg)/(n*d) Expression 4

In Expression 4, d is the distance between the pinholes in the mask 20, λ is the wavelength of the light beam from the illumination optical system 10, and n and m are constants (1, 2, 3 . . . ).

The measurement accuracy may also be improved by separating the peaks of the Fourier spectrum of the interference fringe apart from each other, by making the light beams from the pinhole and the opening that are not adjacent to each other interfere with each other to reduce the pitch of the interference fringe.

The wave aberration of the optical system TOS can be measured not only at one point on the object plane of the optical system TOS but also at any point on the object plane, by moving the mask 20 and the mirror 30. This may be achieved by driving the mask 20 such that an arbitrary point on the object plane conforms to the point P and by driving the mirror 30 such that its focal position conforms to the position where the light transmitted through the point P is condensed by the optical system TOS.

Moreover, the measurement does not need to be performed in a state in which the measuring device is incorporated in the exposure apparatus. The wave aberration of the projection optical system may be measured outside the exposure apparatus, and the wave aberration of an optical system other than the projection optical system of the exposure apparatus may be measured.

Furthermore, the measuring device 1 may further have an adjustment unit that adjusts the lens distance of the optical system TOS, and a feedback control mechanism that reduces the wave aberration of the optical system TOS. For example, the wave aberration of the optical system TOS is measured, and the arithmetic unit calculates the driving amount of an actuator in a correction unit using the result of measurement. Then, the actuator is driven by the calculated driving amount.

Furthermore, after the adjustment is performed, using the aberration-adjusted (projection) optical system TOS, the reticle having the patterns of devices is illuminated to project the image of the patterns on the reticle on a wafer (an exposure processing). Thereafter, known steps, such as development and etching, are performed to form the devices, such as semiconductor devices. Thus, the devices are manufactured.

As has been described, according to this embodiment, by forming a double-path interferometer, the optical property of an optical system can be accurately measured using a simple structure. Furthermore, the optical property thereof can be more accurately measured even with a light source having a low spatial coherence, such as an exposure light source.

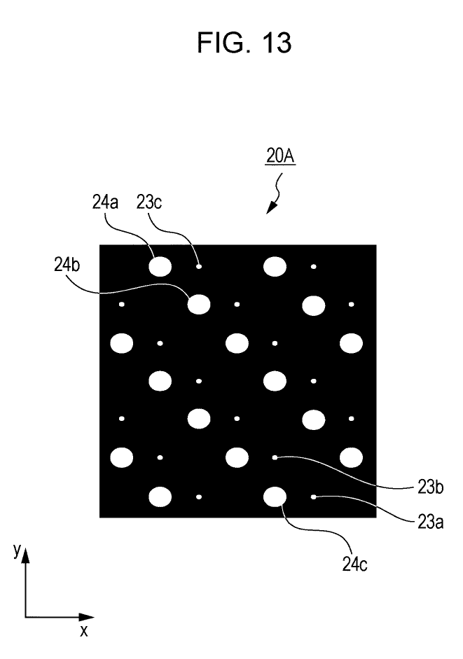

A second embodiment of the present invention will be described below. In this embodiment, instead of the mask 20, a mask 20A shown in FIG. 13 is used. In addition, the illumination optical system forms a predetermined effective light source distribution according to the configuration of the mask 20A.

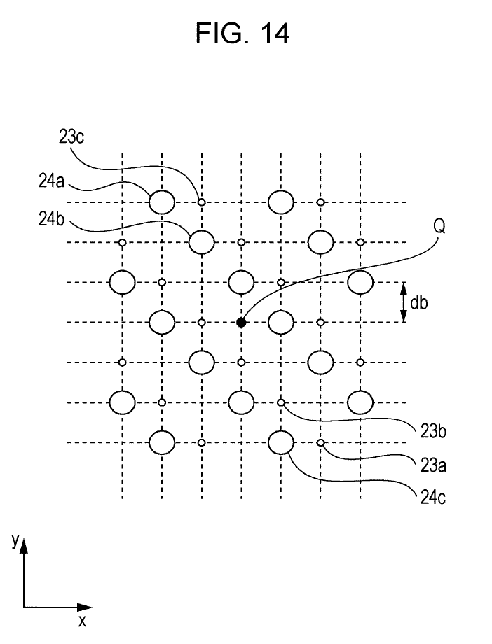

FIG. 13 shows a plan view of the mask 20A. The mask 20A has a plurality of pinholes and openings that are arranged periodically on a two-dimensional surface. As shown in FIG. 14, a plurality of pairs, each including one pinhole and one opening that are adjacent to each other, are arranged at equal intervals in the x direction (first direction), and a plurality of pairs are also arranged at equal intervals in the y direction (second direction) that is perpendicular to the x direction. The distance between the paired pinhole and opening is db.

Furthermore, one pinhole and one opening having a larger diameter than the pinhole, forming a pair, are arranged point-symmetrically with respect to a point Q. More specifically, a pinhole 23a and an opening 24a, forming a pair, are arranged point-symmetrically with respect to the point Q. Similarly, a pinhole 23b and an opening 24b, and a pinhole 23c and an opening 24c are arranged point-symmetrically with respect to the point Q.

The diameter of the pinholes and the diameter of the openings in the mask 20A are the same as those in the mask 20. Accordingly, the wave of light having passed through the pinholes in the mask 20A is an ideal spherical wave. Furthermore, the openings in the mask 20A have a diameter such that the aberration of the optical system TOS is not eliminated by the transmitted light.

The pinholes and openings in the mask 20A are also arranged at such a distance from each other that the light beam from at least one pinhole and the light beam from at least one opening have coherence.

Assuming that light passes through the mask 20A at the point Q, the mirror 30 is disposed such that the focal position thereof is aligned with the position where the optical system TOS condenses light having passed at the point Q. The coordinate origin of the optical system TOS on the object side is disposed at the point Q and that on the image side is disposed at the position where the optical system TOS condenses light having passed at the point Q.

A case where a region including, for example, the openings 24a and 24b and the pinhole 23c is illuminated will be discussed. For example, light having passed through the opening 24a passes the optical system TOS, is reflected at the mirror 30, passes again through the optical system TOS, and is condensed at the position point-symmetrical to the opening 24a with respect to the point Q (pinhole 23a). Similarly, light having passed through the opening 24b passes through the optical system TOS, is reflected at the mirror 30, passes again through the optical system TOS, and passes through the pinhole 23b. These rays of light are reference waves and become ideal spherical waves by passing through the pinholes 23.

On the other hand, light having passed through the pinhole 23c passes through the optical system TOS, is reflected at the mirror 30, passes again through the optical system TOS, and passes through the opening 24c. This is light to be measured. Because the light has passed through the pinhole 23c before passing through the optical system TOS, the light is not affected by the aberration of the illumination optical system, and, because the light has passed through the opening 24c after passing through the optical system TOS, the wave contains the aberration of the optical system TOS.

The illumination optical system 10 forms the effective light source distribution, taking into consideration the coherence length and coherence direction of the light beams having passed through the mask 20A. The illumination optical system 10 forms the effective light source distribution such that the light beam from a pinhole in the mask 20A is coherent only with the light beam from the opening adjacent to the pinhole.

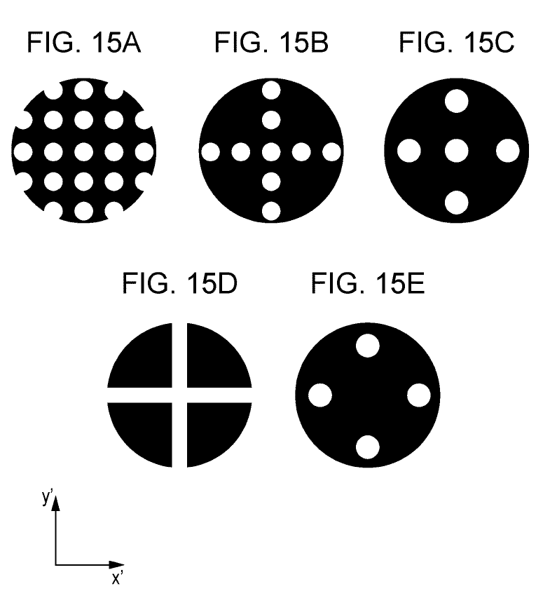

For example, the illumination optical system 10 forms the effective light source distributions as shown in FIGS. 15A to 15E. White portions in black circles are light-emitting portions. When a region including the openings 24a and 24b and the pinhole 23c is illuminated with these effective light source distributions, the light beam from the opening 24c is coherent only with the light beams from the pinholes 23a and 23b, which are distant from the opening 24c by the same distance in the x and y directions. Thus, the light beam from the opening 24c hardly interferes with the light beams from the pinholes other than the pinholes 23a and 23b. This applies not only to the pinholes 23a and 23b and the opening 24c, but also to the other pinholes and openings in the mask 20A.

As has been described above, with these effective light source distributions, the reference light having passed through each of the pinholes 23a and 23b interferes with the light to be measured, having passed through the opening 24c, forming interference fringes. That is, among three opening-pinhole pairs, light to be measured, formed at each of two pairs, is made to interfere with the reference light formed at the remaining pair. Alternatively, among three opening-pinhole pairs, light to be measured, formed at one pair, is made to interfere with the reference light formed at each of the other two pairs. However, the light beams having passed through the openings do not interfere with each other because of the low coherence. Accordingly, the interference between the light beams having passed through the openings in the mask 20A hardly affects the measurement accuracy.

The detector 60 detects (picks up the image of) an interference fringe having a plurality of superimposed interference patterns, each of which is formed by three light beams, namely, the light beam that passes through the opening (for example, the opening 24c) after passing through the optical system TOS and the two light beams that pass through the pinholes (for example, the pinholes 23a and 23b) after passing through the optical system TOS.

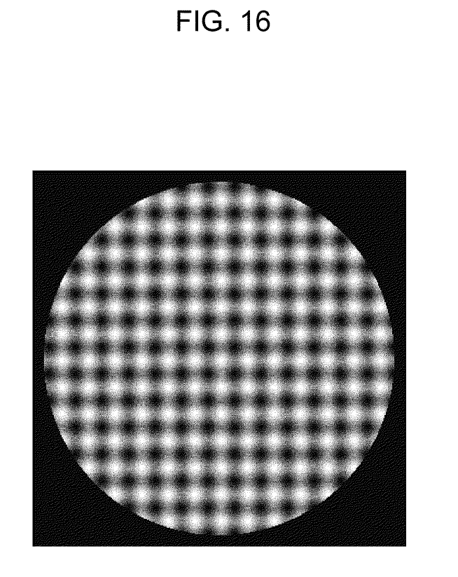

The above-mentioned three light beams form, on the detector 60, the interference patterns that are superimposed on one another so as to be shifted in the X and Y directions by an integral multiple of the distance 3db (db is the distance between the adjacent pinhole and opening). FIG. 16 shows an interference pattern formed by the light beam having passed through the optical system TOS and the mask 20A, when the entire surface of the mask 20A is illuminated with the effective light source distributions shown in FIGS. 15A to 15E. In this case, a four-fold symmetry pattern as shown in FIG. 16 results. Although FIG. 16 shows a case where the optical system TOS has no aberration, an optical system TOS having an aberration will produce a different pattern.

Because the distance db is sufficiently small and the pinholes are arranged at a high density, the light intensity can be increased without reducing the measurement accuracy. Although the light intensity can be further increased by increasing the number of pinholes, because the interference patterns are also superimposed in a shifted manner, an increase in the region (area) where the pinholes are disposed may decrease the contrast. Accordingly, it is desirable that the region where the pinholes and openings are disposed (i.e., the region to be illuminated) in the mask 20A be equal to or smaller than one tenth of the pitch of the interference fringes.

Similarly to the first embodiment, the electron moiré method or the Fourier transformation method is used to obtain the phase information of the wave aberration of the optical system TOS from the interference pattern detected by the detector 60. When the electron moiré method is used, there are two types of cosine functions by which the interference pattern is multiplied. These cosine functions have frequencies in the x and y directions and have different phases. By multiplying the interference fringe by each function and by performing the Fourier transformation or an arctangent calculation, the wave aberration can be obtained. When the Fourier transformation method is used, because peaks with four-fold symmetry appear in the Fourier space when the interference pattern is Fourier-transformed, information near the two peaks orthogonal to each other may be used. Two wave aberrations can be obtained by the electron moiré method or the Fourier transformation method, and, if there is no measurement error at all, the two wave aberrations are equal. However, in practice, the two wave aberrations are often different from one another because of the presence of a measurement error. Thus, it is desirable to reduce the measurement error by, for example, calculating the average of the two wave aberrations.

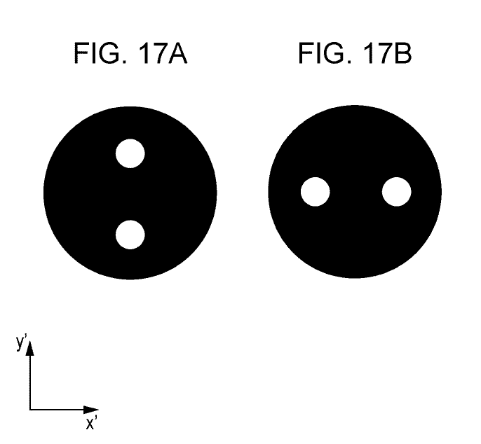

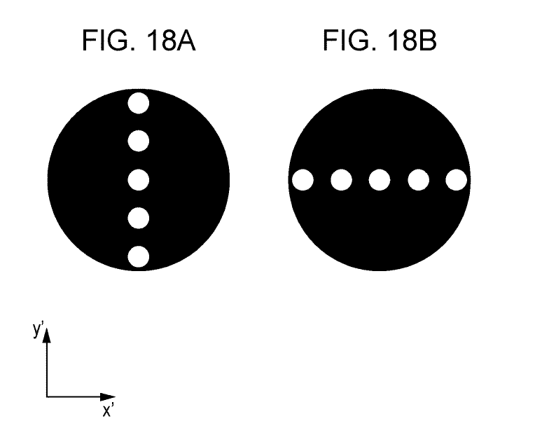

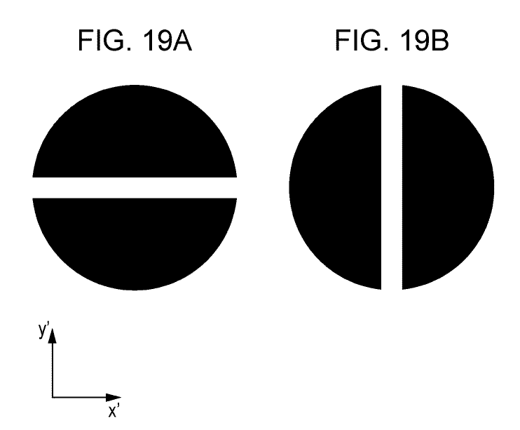

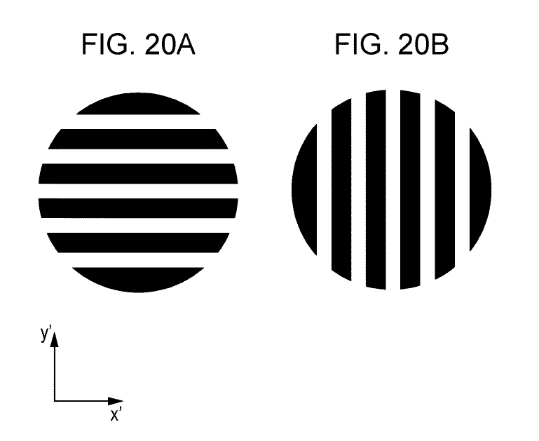

Furthermore, the measurement accuracy of the wave aberration of the optical system to be measured can be improved by making the illumination optical system 10 illuminate the mask 20A with the effective light source distributions as shown in FIGS. 17A and 17B and form a double-path interferometer. The same is true with the effective light sources shown in FIGS. 18A and 18B, FIGS. 19A and 19B, and FIGS. 20A and 20B.

More specifically, using the effective light source distributions shown in FIGS. 17A, 18A, 19A, and 20A, the coherence between the light beam having passed through the pinhole 23b and that having passed through the opening 24c is increased to detect the interference pattern. Similarly, using the effective light source distributions shown in FIGS. 17B, 18B, 19B, and 20B, the coherence between the light beam having passed through the pinhole 23a and that having passed through the opening 24c is increased to detect the interference pattern.

Although the illumination optical system 10 forms two effective light source distributions, namely, A and B in FIGS. 17 to 20, it is also possible that the illumination optical system 10 forms one effective light source distribution, for example, A in FIGS. 17 to 20, and the optical system TOS is rotated. Alternatively, one of the two effective light source distributions, namely, A and B in FIGS. 17 to 20, may be rotated.

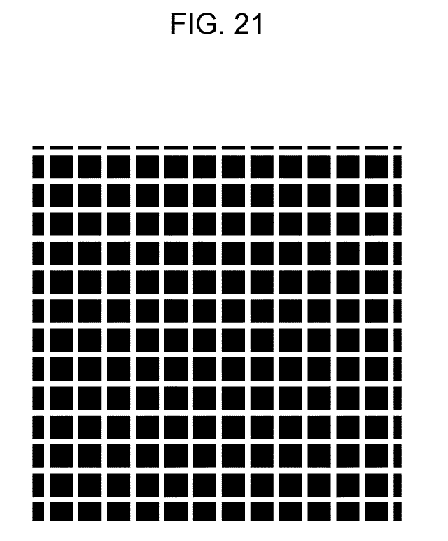

Furthermore, similarly to the first embodiment, the coherence may be controlled by disposing, not the effective light source distribution formed by the illumination optical system 10, but the diffraction grating as shown in FIG. 21, serving as a light splitter, between the illumination optical system 10 and the mask 20A. The diffraction grating has transmitting portions disposed such that the light beam from a pinhole in the mask 20A is coherent only with those from the openings adjacent to the pinhole in the X and Y directions. FIG. 21 is a schematic plan view of a diffraction grating serving as a light splitter.

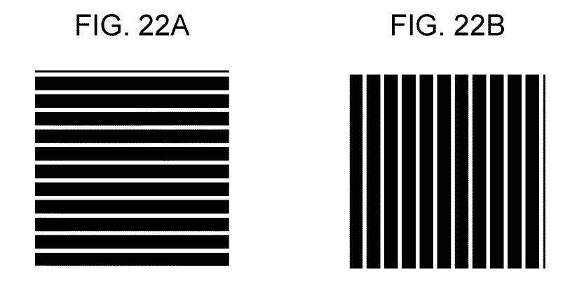

Moreover, it is also possible to improve the measurement accuracy of the wave aberration of the optical system to be measured by disposing two diffraction gratings, serving as the light splitters, shown in FIGS. 22A and 22B in the optical path so as to be switchable. FIGS. 22A and 22B are schematic plan views of diffraction gratings serving as light splitters.

Because the pitches of the interference fringes, detected by the detector 60, are orthogonal to each other, analysis can be performed more easily and accurately than the first embodiment.

As has been described, with the measuring device according to this embodiment, the optical property of an optical system can be accurately measured using a simple structure. Furthermore, the optical property thereof can be more accurately measured even with a light source having a low spatial coherence, such as an exposure light source.

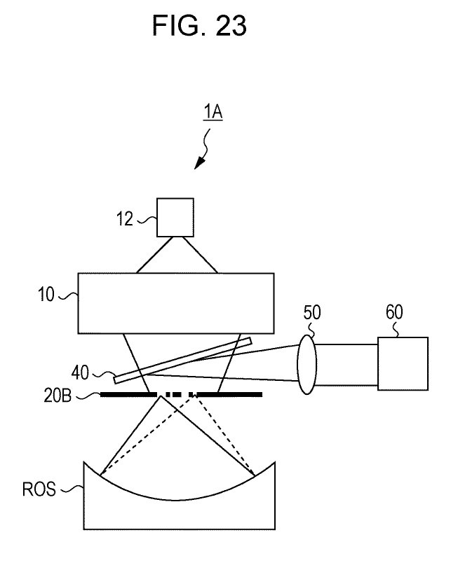

A third embodiment of the present invention will be described below. FIG. 23 is a schematic view showing the structure of a measuring device according to a third embodiment of the present invention. A measuring device 1A according to this embodiment measures the shape of the surface to be measured of a concave spherical mirror ROS. The measuring device 1A includes, at least, an illumination optical system 10, a half mirror 40, an image-forming lens 50, and a detector 60.

The illumination optical system 10 illuminates a mask 20B with Koehler illumination. The mask 20B serves as a plane to be illuminated of the illumination optical system 10 and is disposed on a focal plane of the spherical mirror ROS.

The configuration of the mask 20B may be the same as that of the mask 20 according to the first embodiment and the mask 20A according to the second embodiment, and the point P (Q), serving as the center of symmetry, is disposed so as to conform to the focal point of the spherical mirror ROS.

Similarly to the first and second embodiments, the illumination optical system 10 forms the effective light source distributions as shown in FIGS. 4A to 4E, 7A to 10C, 15A to 15E, and 17A to 20B such that only the light beams from adjacent openings and pinholes in the mask 20B have coherence. As described above, a diffraction grating may also be used instead of forming the effective light source distribution.

In this embodiment, when the illumination optical system 10 illuminates the mask 20B, light (indicated by a thick solid line in FIG. 23) having passed through the openings is reflected at the spherical mirror ROS, and the reflected light (indicated by a dotted line in FIG. 23) passes through the pinholes. This ray of light is an ideal spherical wave (reference light).

The light having passed through the pinholes is reflected at the spherical mirror ROS and passes through the openings. This ray of light is a wave having information of the surface shape of the spherical mirror ROS (light to be measured). These two rays are reflected at the half mirror 40, pass through the image-forming lens 50, and form an interference fringe on the detector 60. By analyzing this interference fringe using the electron moiré method or the Fourier transformation method, the surface shape of the spherical mirror ROS can be measured. Then, the spherical mirror ROS can be processed using the measured surface shape.

As has been described above, with the measuring device according to this embodiment, the surface shape of the object to be measured can be accurately measured using a simple structure. Furthermore, the optical property thereof can be more accurately measured even with a light source having a low spatial coherence, such as an exposure light source.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2008-279873, filed Oct. 30, 2008, which is hereby incorporated by reference herein in its entirety.

What is claimed is:

1. A measuring device configured to measure a wave aberration of an optical system to be measured, comprising:
an illumination optical system configured to illuminate a mask disposed on a plane to be illuminated with light from a light source;
a reflection optical element configured to reflect light, having passed through the mask and the optical system to be measured, into the optical system to be measured; and
a detector configured to detect an interference fringe formed by the light having passed through the mask,
wherein the mask has at least three pinhole-opening pairs, each including one pinhole and one opening having a larger diameter than the pinhole that are arranged point-symmetrically, the three pinhole-opening pairs having a common center of symmetry, in each of the pinhole-opening pairs, light having passed through the pinhole and the optical system to be measured, been reflected at the reflection optical element, and passed through the optical system to be measured and the opening serving as light to be measured, and light having passed through the opening and the optical system to be measured, been reflected at the reflection optical element, and passed through the optical system to be measured and the pinhole serving as reference light, and
wherein the light to be measured formed in at least two of the three pairs is made to interfere with the reference light formed in the remaining pair, or, the light to be measured formed in at least one of the three pairs is made to interfere with the reference light formed in the other two pairs.

2. The measuring device according to claim 1, wherein the pinholes and the openings are alternately arranged at vertices of a regular hexagon.

3. The measuring device according to claim 1, wherein the mask has a plurality of the pinhole-opening pairs arranged in a first direction and a plurality of the pinhole-opening pairs arranged in a second direction perpendicular to the first direction.

4. An exposure apparatus configured to illuminate a reticle with light from a light source to project an image of a pattern on the reticle onto a substrate through a projection optical system, the exposure apparatus comprising:
the measuring device according to claim 1 configured to measure a wave aberration of the projection optical system serving as an optical system to be measured; and
an adjustment unit for adjusting the wave aberration of the projection optical system using a result of measurement by the measuring device.

5. A device manufacturing method comprising the steps of:
exposing a substrate using the exposure apparatus according to claim 4 while adjusting the wave aberration of the projection optical system;
developing the exposed substrate; and
forming a device from the developed substrate.

6. A measuring device configured to measure the shape of a surface to be measured, comprising:
an illumination optical system configured to illuminate a mask disposed on a plane to be illuminated with light from a light source; and
a detector configured to detect an interference fringe formed by the light having passed through the mask,
wherein the mask has at least three pinhole-opening pairs, each including one pinhole and one opening having a larger diameter than the pinhole that are arranged point-symmetrically, the three pinhole-opening pairs having a common center of symmetry, in each of the pinhole-opening pairs, light having passed through the pinhole, been reflected at the surface to be measured, and passed through the opening serving as light to be measured, and light having passed through the opening, been reflected at the surface to be measured, and passed through the pinhole serving as reference light, and
wherein the light to be measured formed in at least two of the three pairs is made to interfere with the reference light formed in the remaining pair, or, the light to be measured formed in at least one of the three pairs is made to interfere with the reference light formed in the other two pairs.
